(19) United States
(12) Patent Application Publication
(10) Pub. No.: US 2006/0236932 A1
(43) Pub. Date: Oct. 26, 2006

(54) Plasma processing apparatus

(76) Inventors: Kenetsu Yokogawa, Tsurugashima-shi (JP); Kenji Maeda, Kudamatsu-shi (JP); Hiroyuki Kobayashi, Tokyo (JP); Masaru Izawa, Tokyo (JP); Tadamitsu Kanekiyo, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/201,243

(22) Filed: Aug. 11, 2005

(30) Foreign Application Priority Data
Apr. 22, 2005 (JP) 2005-125227

(51) Int. Cl. C23F 1/00; C23C 16/00

(52) U.S. Cl. 118/723 E; 156/345.46

(57) ABSTRACT

The invention provides a plasma processing apparatus capable of preventing the production of particle and preventing the influence of particle on the sample. The plasma processing apparatus comprises a vacuum chamber; process gas introducing means for introducing process gas into the vacuum chamber; means, coupled to a first RF power supply, for applying RF energy to the process gas introduced into the vacuum chamber to turn the process gas into plasma; a sample mounting electrode for mounting a sample on an upper surface thereof and holding the sample in the vacuum chamber; evacuation means for evacuating the process gas in the vacuum chamber; and plasma confining means, provided on a peripheral side of the mounting electrode in the vacuum chamber, for inflecting flow of the process gas caused by the evacuation means on a downstream side of a sample mounting surface of the mounting electrode to prevent plasma from diffusing downstream of the sample mounting surface.

The present application is based on and claims priority of Japanese patent application No. 2005-125227 filed on Apr. 22, 2005, the entire contents of which are hereby incorporated by reference.

### BACKGROUND OF THE INVENTION

1. Field of the Invention

This invention relates to a plasma processing apparatus, and more particularly to a plasma processing apparatus capable of preventing the influence of particle.

2. Description of the Related Art

In a dry etching apparatus, process gas is introduced into a vacuum chamber equipped with an evacuating means. The introduced process gas is turned into plasma by electromagnetic waves. A sample (e.g., a workpiece such as a wafer) is exposed to the plasma to etch its surface except its masked portion, and thus a desired feature is obtained.

An RF voltage, different from the plasma generating voltage, is applied to the sample. The RF voltage accelerates ions in the plasma and causes them to impinge on the sample surface, thereby enhancing the etching efficiency and achieving the verticality of processed features.

The etching feature and the etching rate are also significantly affected by electrically neutral active species in addition to the above-described impingement of ions. The distribution of impingement of neutral active species on the sample surface is significantly affected by the plasma distribution and the flow of supplied process gas.

For this reason, even if uniform plasma is generated, nonuniformity in the flow of process gas toward the sample will cause nonuniformity in the etching feature and in the rate distribution within the sample surface. In a known arrangement for producing uniform flow of process gas relative to the sample, the gas is fed like a shower from a surface opposed to the sample and the evacuation port of a vacuum pump serving as a gas evacuating means is located directly below the sample mounting electrode.

According to this arrangement, the supplied gas is provided with improved, especially axial, symmetry relative to the sample surface. However, this method reduces ease of maintenance for the sample mounting electrode and makes it difficult to install a mechanism for driving a sample conveying means used for arbitrarily setting the processing position of the sample. Moreover, in such an arrangement where gas is fed like a shower from a surface opposed to the sample and the evacuation port of a vacuum pump serving as a gas evacuating means is located directly below the sample mounting electrode, fine particles accumulated on the lower side face of the sample mounting electrode and on the vacuum chamber wall around the evacuation port are stirred up during plasma generation, which may be attached to the sample surface to cause particle contamination.

Since plasma is easy to diffuse around the evacuation port, the diffused plasma deteriorates the vacuum chamber wall, which is associated with particle contamination. While particle production may be reduced by using yttria or other material with excellent plasma resistance for the vacuum chamber wall, coating the entire area with yttria would increase cost because such material is expensive.

As a technology for solving the above-described problem with particles, Japanese Laid-Open Patent Application 2002-184766, for example, discloses a plasma processing apparatus in which a discharge producing electrode placed on the surface opposite to a sample is subjected to a voltage having the same frequency as an RF voltage applied to the sample but being 180° out of phase. That is, the discharge producing electrode is subjected to an RF voltage being 180° out of phase relative to the RF voltage applied to the sample. In other words, during a period when a positive RF voltage is applied to the sample, a negative voltage is applied to the opposite electrode. This prevents the increase of plasma potential and the sputtering of the vacuum chamber wall. In this way, wear out of wall material and particle production from the wall material can be prevented.

According to the foregoing conventional technology, particle production can be prevented as described above. However, if the plasma processing apparatus is continuously used over time, particles are accumulated in the lower part or around the evacuation port of the vacuum chamber, which is associated with fine particle. Such particle is an obstacle to meeting the demands of device manufacture for an increasingly higher precision.

### SUMMARY OF THE INVENTION

In light of these problems, the invention provides a plasma processing apparatus capable of preventing the production of particle and preventing the influence of particle on the sample.

In order to solve the above problems, the invention employs the following configuration.

A plasma processing apparatus comprises a vacuum chamber; process gas introducing means for introducing process gas into the vacuum chamber; means, coupled to a first RF power supply, for applying RF energy to the process gas introduced into the vacuum chamber to turn the process gas into plasma; a sample mounting electrode for mounting a sample on an upper surface thereof and holding the sample in the vacuum chamber; evacuation means for evacuating the process gas in the vacuum chamber; and plasma confining means, provided on a peripheral side of the mounting electrode in the vacuum chamber, for inflecting flow of the process gas caused by the evacuation means on a downstream side of a sample mounting surface of the mounting electrode to prevent plasma from diffusing downstream of the sample mounting surface.

Because of the above configuration, the invention can provide a plasma processing apparatus capable of preventing the production of particle and preventing the influence of particle on the sample.

### BRIEF DESCRIPTION OF THE DRAWINGS

FIG. 1 illustrates a plasma processing apparatus according to a first embodiment of the invention.

FIG. 2 illustrates more specifically the plasma confining means 7 formed from two annular plates.

FIG. 3 illustrates another example of the plasma confining means 7.

FIG. 4 illustrates a plasma processing apparatus according to a second embodiment of the invention.

FIG. 5 illustrates more specifically the plasma confining means 19 in FIG. 4.

FIG. 6 illustrates a plasma processing apparatus according to a third embodiment of the invention.

FIG. 7 illustrates more specifically the plasma confining means 21 in FIG. 6.

### DETAILED DESCRIPTION OF THE PREFERRED EMBODIMENTS

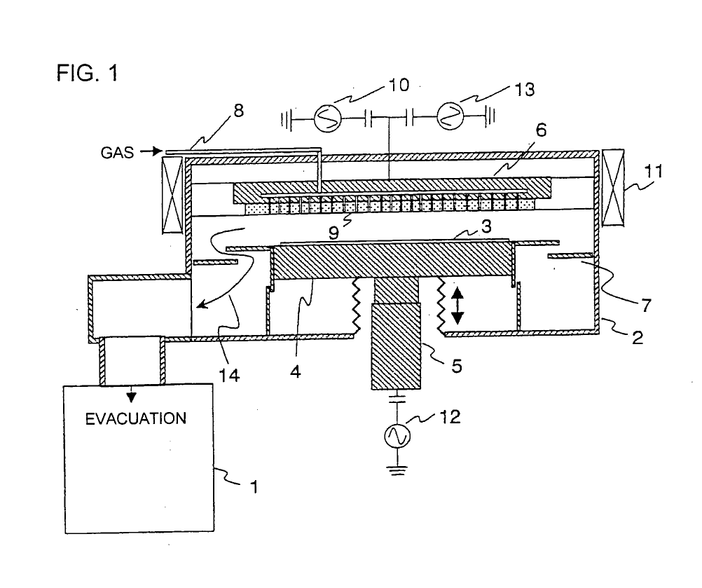

Preferred embodiments will now be described with reference to the accompanying drawings. FIG. 1 illustrates a plasma processing apparatus according to a first embodiment of the invention. As shown in FIG. 1, the plasma processing apparatus comprises a vacuum chamber 2 evacuated by an evacuating means 1, a sample mounting electrode 4 for mounting a sample 3 in the vacuum chamber 2, and an upper electrode 6 located on a surface opposite to the sample 3.

A plasma confining means 7 composed of two annular plates is placed between the sample mounting electrode 4 and the inner wall of the vacuum chamber 2. The sample mounting electrode 4 is also equipped with a vertical driving mechanism 5 capable of driving the mounting means vertically and adjusting the relative distance between the sample 3 and the upper electrode 6.

The upper electrode 6 is equipped with a shower plate 9 for spreading process gas fed from a process gas introducing means 8 and supplying it onto the surface of the sample 3. Plasma is generated between the sample 3 and the upper electrode 6 by RF energy supplied from a first RF power supply 10, which is connected to the upper electrode 6. In this embodiment, a power supply having a frequency of 200 MHz is used for the first RF power supply 10 for discharge production.

The density distribution of plasma is controlled by magnetic field generated by a magnetic field generating means 11. A third RF power supply 12 is connected to the sample 3 via the sample mounting electrode 4. The energy of ions impinging from the plasma on the sample 3 is controlled by an RF voltage applied by the third RF power supply 12. The shower plate 9 placed on the upper electrode 6 is also supplied with an RF voltage from a second RF power supply 13 that is different from the above-mentioned first RF power supply 10 for discharge production. Based on this, the energy of ions impinging on the shower plate 9 can be controlled independently of discharge production.

The third RF power supply 12 for applying RF voltage to the sample 3 and the second RF power supply 13 for applying RF voltage to the shower plate 9 have the same frequency, but are set to be 180° out of phase relative to each other. In this embodiment, the RF power applied to the sample 3 and the shower plate 9 has a frequency of 4 MHz.

Next, the operation of the plasma processing apparatus of this embodiment is described. In this embodiment, a 200 MHz RF power supply (first RF power supply) is used for the plasma generating power supply. Through interaction between electric field generated by this power supply and magnetic field generated by the magnetic field generating means 11, plasma can be generated in the range of low to high pressures (generally 0.1 to 20 Pa). Moreover, use of a frequency of 200 MHz, which is a relatively high frequency for parallel plate discharge, facilitates achieving a high efficiency of plasma generation, and also facilitates preventing the increase of plasma potential, thereby preventing excessive wearout of members at ground potential such as the vacuum chamber wall due to the sputtering effect.

Furthermore, RF voltage having the same frequency (4 MHz) but being 180° out of phase applied to the sample 3 and the shower plate 9 opposed thereto facilitates accelerating and attracting ions from plasma to the surface of the sample and the shower plate, and prevents the increase of plasma potential. This prevents any excessive sputtering effect on members at ground potential such as the vacuum chamber wall.

In addition, prevention of the increase of plasma potential as described above also leads to reducing the extent to which the plasma generated between the sample 3 and the shower plate 9 is diffused downstream of the vacuum chamber (in the direction of the evacuating means 1). However, it cannot completely prevent the diffusion of plasma downstream of the vacuum chamber. If plasma is diffused into the downstream region of the vacuum chamber, reaction products may be deposited as particle on the vacuum chamber wall in that region, and/or the vacuum chamber wall per se is altered into fine particle being accumulated. The accumulated particle may be stirred up to contaminate the surface of the sample 3, thereby decreasing the production yield of semiconductor devices. The particle cannot be removed unless the vacuum chamber is opened and cleaned manually, since the cleaning effect of oxygen plasma does not sufficiently extend to the downstream region of the vacuum chamber. That is, the particle accumulated in the lower part of the vacuum chamber is also a significant factor to decreasing the availability of the apparatus. For this reason, in this embodiment, a plasma confining means 7 formed from two annular plates is placed as shown in FIG. 1.

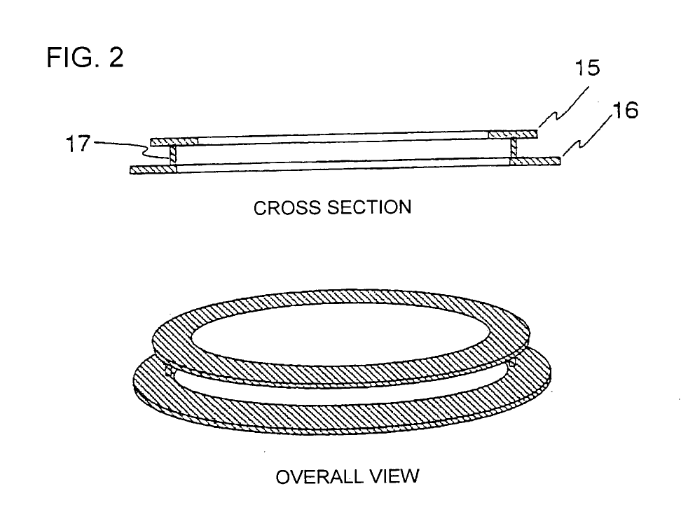

FIG. 2 illustrates more specifically the plasma confining means 7 formed from two annular plates. The plasma confining means 7 comprises two annular plates, i.e., an upper annular plate 15 and a lower annular plate 16, which are fixed via a support 17 so as to overlap each other. The plasma confining means is configured so that gas flow (arrow 14) supplied from the shower plate 9 onto the upper surface of the sample 3 is inflected one or more times to reach the evacuation means 1. This enables the confining means to capture particles constituting the plasma. Thus the plasma confining means 7 as placed in this way can prevent plasma from diffusing downstream thereof.

In this embodiment, RF voltage being 180° out of phase applied to the upper electrode 6 and the sample mounting electrode 4 prevents the increase of plasma potential as described above. For this reason, diffusion of plasma downstream of the vacuum chamber can be sufficiently prevented even when the plasma confining means 7 having a relatively large opening as shown in FIGS. 1 and 2 is used. That is, even the plasma confining means 7 having a relatively large opening can shield plasma from spreading to the evacuation means. This implies that the decrease of gas evacuation rate can be minimized. Therefore a process with low pressure and large flow rate can be easily constructed.

As described above, diffusion of plasma can be prevented by inflecting gas flow one or more times. However, if the plasma processing is continued over time, particle including neutral active particles is eventually accumulated in the lower part of the vacuum chamber. In this case, the accumulated particle may be stirred up by electrical action due to the arrival of plasma. However, in this embodiment, the risk of stirring up particle is significantly reduced because plasma per se does not reach the particle. In addition, even if the particle is accidentally stirred up for any reason, it needs to pass the plasma confining means 7 inflected one or more times before reaching the surface of the sample 3 from the lower part of the vacuum chamber. It should be noted here that the mean free path of fine particle in the vacuum is as much long as several centimeters to tens of centimeters. For this reason, the labyrinth structure of the plasma confining means 7 functions effectively, and thus the probability of arrival of the particle on the upper surface of the sample 3 can be significantly reduced.

In the embodiment shown in FIG. 1, the sample mounting electrode 4 is equipped with a vertical driving mechanism 5. The plasma confining means 7 is fixed to the sample mounting electrode 4. Therefore, when the vertical driving mechanism 5 moves the sample mounting electrode 4 vertically, the plasma confining means 7 is also moved vertically at the same time. According to this structure, for any processing position of the sample 3, the plasma confining means 7 is always placed at the same position relative to the sample 3, and thus the diffusion downstream of the vacuum chamber can be effectively prevented. In this embodiment, the relative position of the plasma confining means 7 can be varied by the vertical driving mechanism 5. It is understood, however, that an equivalent effect is also achieved when the plasma confining means 7 is fixed to a certain position.

Preferably, the plasma confining means 7 in this embodiment is configured to have a conductance for gas flow such that the pressure difference between the upstream side (sample 3 side) and the downstream side (evacuation means 1 side) of the plasma confining means 7 is 1.1 times or more. According to experiments, a labyrinth structure yielding such a conductance can effectively prevent plasma diffusion and also prevent contamination of the sample surface due to stirring up of particle from the lower part of the vacuum chamber. If the pressure difference between the upstream and downstream sides of the plasma confining means 7 is less than 1.1 times, especially the effect of preventing particle from stirring up from the lower part of the vacuum chamber is decreased. In addition, gas flow caused by the pressure difference described above creates a push-back effect on particle, which can also effectively reduce the probability of arrival of particle on the sample.

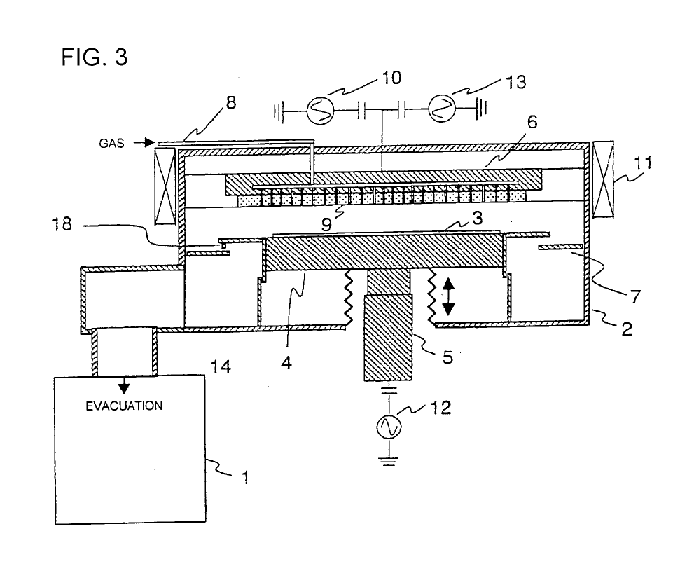

FIG. 3 illustrates another example of the plasma confining means 7. In this example, a feature 18 for partially decreasing the conductance for gas flow is attached to a portion of the plasma confining means 7 in its circumferential direction.

When the evacuation means 1 is placed asymmetrically relative to the sample 3 (rather than directly below the sample 3) as shown by the example in FIG. 1, the evacuation efficiency is higher on the side nearer to the evacuation means 1 (left side in FIG. 1). Even if process gas is supplied uniformly via the shower plate 9, the gas supply on the sample surface may be biased toward the evacuation means 1 side.

For this reason, as shown in FIG. 3, a feature 18 (e.g., an arc-shaped protrusion formed on the lower face of the upper annular plate 15) for partially decreasing the conductance for gas flow is attached to the plasma confining means 7 on the evacuation means 1 side. This virtually equalizes the gas evacuation performance in the circumferential direction around the sample mounting electrode 4, which enables uniform gas-supply onto the surface of the sample 3.

In the example of FIG. 3, nonuniformity of process gas supply onto the sample surface due to asymmetry of the evacuation structure is avoided by placing a feature 18 for partially decreasing the conductance for gas flow. Alternatively, the overlapping area and gap spacing of two or more plate members of the confining means shown in the embodiment of FIG. 1 can be varied to make a difference in conductance for gas flow along the circumferential direction of the plasma confining means around the sample.

In this embodiment, the plasma confining means is made of aluminum sprayed with yttria (Y₂O₃) film. However, a similar effect can also be achieved by using any of aluminum, anodized aluminum, aluminum sprayed with ytterbium, stainless steel, silicon, silicon carbide, carbon, aluminum oxide (alumina), quartz, yttria, and ytterbium.

In this embodiment, a 200 MHz RF power supply is used for generating plasma, and 4 MHz power supplies being 180° out of phase are used for supplying RF power to the shower plate 9 and the sample 3. However, a similar effect can also be achieved by using a power supply at 13 to 450 MHz for generating plasma and power supplies at 400 kHz to 14 MHz for supplying RF power to the shower plate and the sample.

In addition, processing can be done by using power supplies other than those having the same frequency and being 180° out of phase for the shower plate 9 and the sample 3. It is also the case when only the sample 3 is subjected to RF power. Moreover, the embodiment can also be adapted to a discharge configuration without magnetic field. Furthermore, the embodiment can also be adapted to inductive coupling processes using electromagnetic waves at 100 kHz to 15 MHz, or magnetic microwave processes using electromagnetic waves at 450 MHz to 2.5 GHz.

However, the power supplies for the shower plate 9 and the sample 3 being 180° out of phase as shown in FIG. 1 effectively prevents the increase of plasma potential and thus can bring out the best performance of the plasma confining means 7.

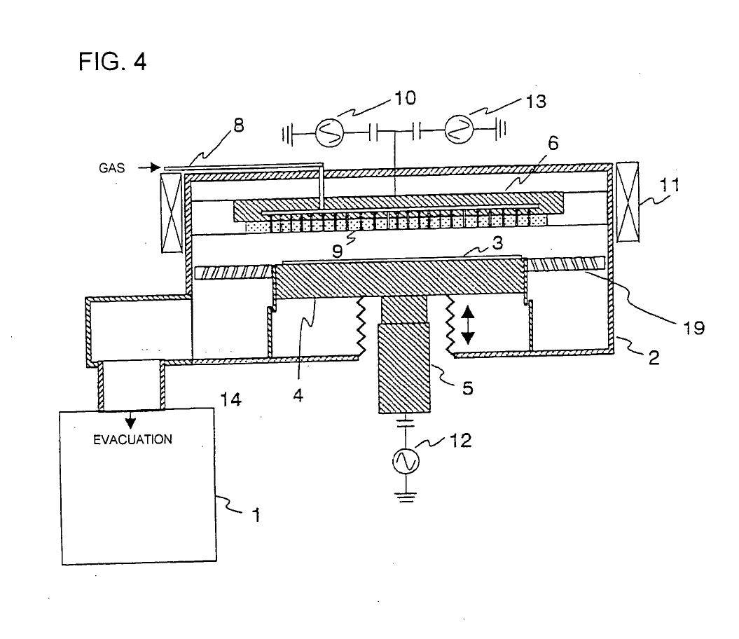

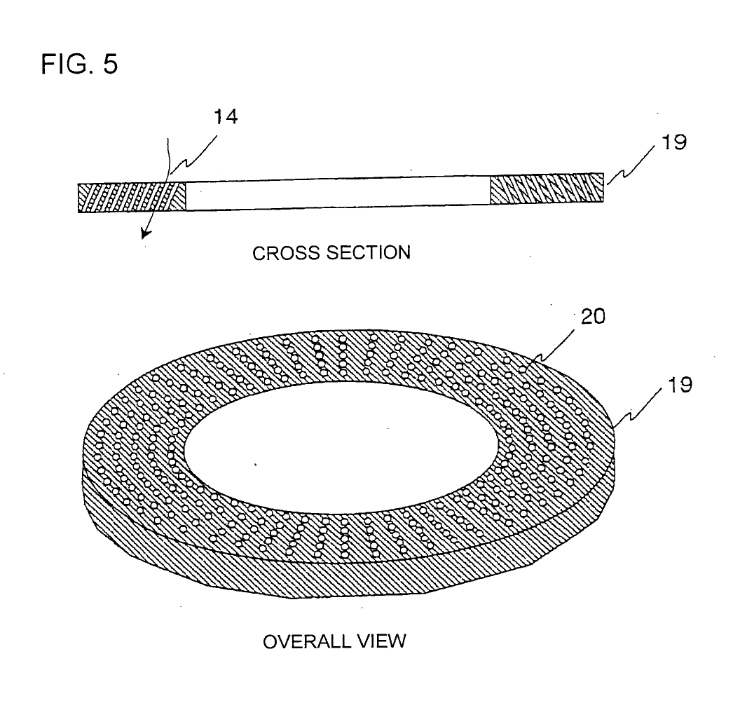

FIG. 4 illustrates a plasma processing apparatus according to a second embodiment of the invention. FIG. 5 illustrates more specifically the plasma confining means 19 in FIG. 4. As shown in FIGS. 4 and 5, the plasma confining means 19 is formed from a single annular plate through which a plurality of pores 20 are formed.

The pores formed through the annular plate constituting the plasma confining means 19 are opened at a certain angle relative to the thickness direction as shown in FIG. 5. The obliquely opened pores can serve to inflect gas flow one or more times, which has an effect similar to that achieved in the first embodiment shown in FIG. 1. In addition, when the aspect ratio (pore depth/pore diameter) of the pore shown in FIG. 5 is 1.5 or more, plasma is effectively shielded and particle is prevented from passing therethrough from the lower part of the vacuum chamber. When the aspect ration is less than 1.5, plasma extinction in the pores is insufficient, which results in passing plasma through the pores and diffusing the plasma downstream of the confining means.

The diameter of the pore, the number (density in the circumferential direction) of pores, and/or the orientation of the obliquely opened pores can be varied along the circumferential direction to reduce nonuniformity of gas flow supplied onto the surface of the sample 3 due to the evacuation means 1 asymmetrically placed relative to the sample 3 as shown in FIG. 3.

This embodiment is the same as the first embodiment described above except for the configuration of the plasma confining means 19. Thus the material of the plasma confining means 19, plasma generating means, and RF voltage applying means for the sample and shower plate are also the same as those in the first embodiment described above.

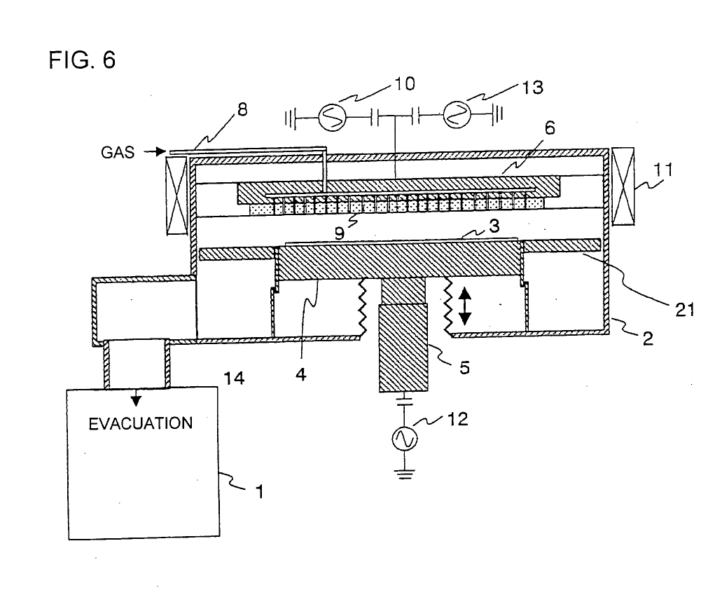

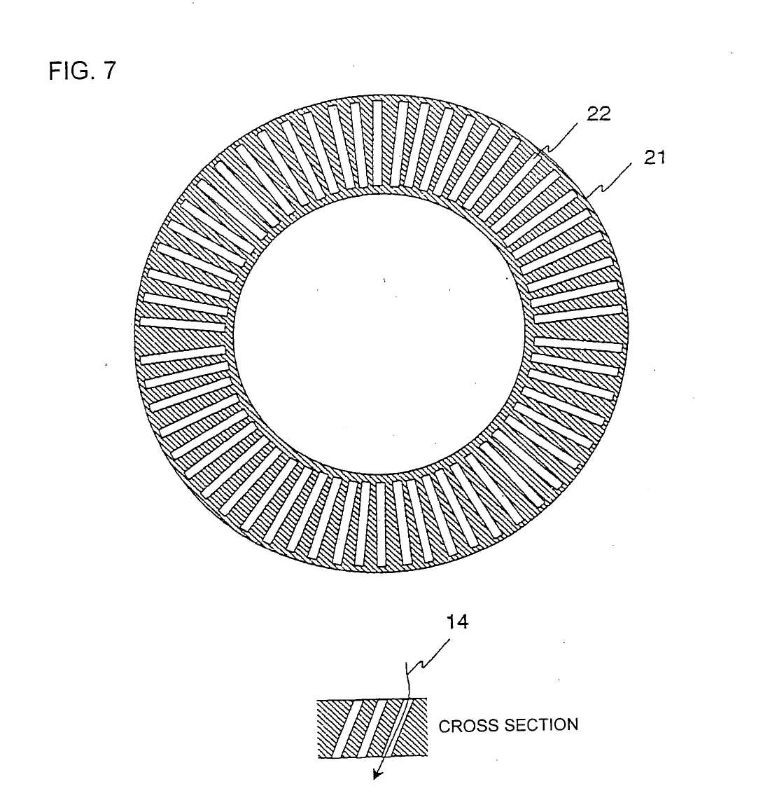

FIG. 6 illustrates a plasma processing apparatus according to a third embodiment of the invention. FIG. 7 illustrates more specifically the plasma confining means 21 in FIG. 6. In this embodiment, as shown in FIGS. 6 and 7, the plasma confining means 21 is formed from a single annular plate through which a plurality of slit apertures 22 are formed. The slit apertures 22 formed through the annular plate are opened at a certain angle relative to the thickness direction as shown in FIG. 7. The obliquely opened slits can serve to inflect gas Flow one or more times, which has an effect similar to that achieved in the first embodiment shown in FIG. 1.

In this embodiment, the width of the slit, the number (circumferential density) of slits, and/or the orientation of the obliquely opened slits can be varied along the circumferential direction to reduce nonuniformity of gas flow supplied onto the surface of the sample 3 due to the evacuation means 1 asymmetrically placed relative to the sample 3 in the first embodiment as shown in FIG. 3.

This embodiment is the same as the first embodiment except for the configuration of the plasma confining means. Thus the material of the plasma confining means 21, plasma generating means, and RF voltage applying means for the sample and shower plate are also the same as those in the first embodiment described above.

As described above, according to the embodiments of the invention, a plasma confining means is provided on the peripheral side of the mounting electrode in the vacuum chamber. By the plasma confining means, gas flow caused by the evacuation means is inflected one or more times on the downstream side of the sample mounting surface of the mounting electrode to prevent plasma from diffusing downstream of the sample mounting surface. The plasma confining means can thus prevent plasma diffusion into the downstream side (the lower part of the vacuum chamber and the vicinity of the evacuation means) thereof, and can prevent deposition of particle, deterioration of the chamber wall, and stirring up of particles in the lower part of the vacuum chamber and around the evacuation means. Moreover, asymmetrization of gas flow on the sample surface due to asymmetric placement of the evacuation means relative to the sample can be prevented by adjusting the position of pores or the like provided in the plasma confining means. Furthermore, even if particles are stirred up in the lower part of the vacuum chamber and around the evacuation means, the structure of inflecting gas flow one or more times can serve to significantly reduce the probability of arrival of particles on the sample surface.

What is claimed is:

1. A plasma processing apparatus comprising:
a vacuum chamber;
process gas introducing means for introducing process gas into the vacuum chamber;
means, coupled to a first RF power supply, for applying RF energy to the process gas introduced into the vacuum chamber to turn the process gas into plasma;
a sample mounting electrode for mounting a sample on an upper surface thereof and holding the sample in the vacuum chamber;
evacuation means for evacuating the process gas in the vacuum chamber; and
plasma confining means, provided on a peripheral side of the mounting electrode in the vacuum chamber, for inflecting flow of the process gas caused by the evacuation means on a downstream side of a sample mounting surface of the mounting electrode to prevent plasma from diffusing downstream of the sample mounting surface.

2. A plasma processing apparatus comprising:
a vacuum chamber;
process gas introducing means for introducing process gas into the vacuum chamber;
means, coupled to a first RF power supply, for applying RF energy to the process gas introduced into the vacuum chamber to turn the process gas into plasma;
a sample mounting electrode for mounting a sample on an upper surface thereof and holding the sample in the vacuum chamber;
evacuation means for evacuating the process gas in the vacuum chamber; and
plasma confining means, provided on a peripheral side of the mounting electrode in the vacuum chamber, for inflecting flow of the process gas caused by the evacuation means on a downstream side of a sample mounting surface of the mounting electrode throughout the periphery of the mounting electrode, the plasma confining means being composed of at least one annular plate, wherein
the plasma confining means produces a pressure difference of 1.1 times or more between the upstream side and the downstream side thereof, and the pressure difference is set to be greater on one portion of the plasma confining means composed of the annular plate than on the other portion thereof, the one portion being located on a side of the plasma confining means where the evacuation means is placed.

3. A plasma processing apparatus as claimed in claim 1 or 2, wherein
the plasma confining means comprises at least one annular plate having pores formed obliquely relative to its surface at an aspect ratio of 1.5 or more.

4. A plasma processing apparatus as claimed in claim 1 or 2, wherein
the plasma confining means comprises at least one annular plate having radially formed slits, the slit having a gas flow axis that is oblique relative to the surface of the annular plate.

5. A plasma processing apparatus as claimed in claim 1 or 2, wherein
the plasma confining means comprises a plurality of annular plates stacked with a spacing in the direction of flow of the process gas and having different inner and outer diameters.

6. A plasma processing apparatus as claimed in claim 1 or 2, wherein
the plasma confining means is composed of any material of aluminum, stainless steel, silicon, silicon carbide, carbon, aluminum oxide, quartz, yttrium oxide, and ytterbium oxide.

7. A plasma processing apparatus as claimed in claim 1 or 2, wherein
the plasma confining means is composed of metal material provided with insulative surface treatment or coating, the coating is a film made from any of yttrium oxide, ytterbium oxide, aluminum oxide, and silicon oxide.

8. A plasma processing apparatus as claimed in claim 1 or 2, wherein
the plasma confining means is capable of being attached to the sample mounting electrode and moving vertically in conjunction with the sample mounting electrode.

9. A plasma processing apparatus as claimed in claim or 2, wherein
the means, coupled to a first RF power supply, for applying RF energy to the process gas introduced into the vacuum chamber to turn the process gas into plasma comprises an antenna electrode, the antenna electrode and the sample mounting electrode are subjected to RF power having the same frequency but being in opposite phases.
